(19) United States
(12) Patent Application Publication
(10) Pub. No.: US 2024/0337566 A1
(43) Pub. Date: Oct. 10, 2024

(54) METHOD FOR MONITORING A MACHINE, COMPUTER PROGRAM PRODUCT AND ARRANGEMENT

(71) Applicant: Siemens Aktiengesellschaft, München (DE)

(72) Inventors: Ali Al Hage Ali, Erlangen (DE); Christian Andreas Wolf Pozzo, Zirndorf (DE); Marco Bögler, Baiersdorf (DE)

(21) Appl. No.: 18/696,710

(22) PCT Filed: Sep. 1, 2022
(86) PCT No.: PCT/EP2022/074341

§ 371 Date: Mar. 28, 2024

(30) Foreign Application Priority Data
Sep. 30, 2021 (EP) 21200255.4

(51) Int. Cl. G01M 99/00

(52) U.S. Cl. CPC G01M 99/005

(57) ABSTRACT

The invention relates to a method (PRC) for monitoring the operation of a machine (MCH), in particular of a motor (ENG) or electrically driven motor (EEG). To improve the monitoring, the method proposes a method of this type comprising the following steps: c) training phase (TPH): i. providing training data (TDT) comprising state variables (PHC) of multiple operating points (OPP) of the machine (MCH), ii. recognizing and combining operating points (OPP) in the training data (TDT) through clustering (CLS) to form operating-point clusters (OCL), i. training a classifier (CLF), which assigns operating points (OPP) to the recognized operating-point clusters (OCL), iv. training an anomaly recognition model (ARM) for recognizing operating anomalies, d) application phase: i. recording operating data (OPD) comprising state variables (PHC) of operating points (OPP) of the machine (MCH) in an operating state, ii. assigning the operating data (OPD) to the operating-point clusters (OCL) using the classifier (CLF), recognizing operating anomalies using the anomaly recognition model (ARM).

### CROSS REFERENCE TO RELATED APPLICATIONS

The present patent document is a § 371 nationalization of PCT Application Serial Number PCT/EP2022/074341, filed Sep. 1, 2022, designating the United States which is hereby incorporated in its entirety by reference. This patent document also claims the benefit of EP21200255.4 filed on Sep. 30, 2021, which is hereby incorporated in its entirety by reference.

### FIELD

Embodiments relate to a method for monitoring the operation of a machine, for example of a motor or electrically driven motor.

### BACKGROUND

Faults and anomalies may occur during the operation of machines, for example of drive systems. These problems may be caused by mechanics, but may also be down to electrical reasons and impact both the motor and the application. If these faults and changes are not recognized early, this leads to increased downtimes and additional and increased maintenance outlay. The monitoring of motor applications is therefore of critical importance for efficient, inexpensive and flexible production. However, this entails technical challenges:

Many machines, for example motor applications (such as pumps and fans) are inverter-driven and thereby have different operating points. During the state monitoring of such applications, the different operating points are typically not considered explicitly or operating point-dependent monitoring does not take place. This leads to faults only being detected too late or not being detected at all. It is likewise not possible to isolate the fault. In addition, the vibration may vary greatly depending on the operating point. Monitoring the general vibration level across all operating points possibly does not make it possible to recognize the different changes within one operating point and thus to detect the onset of damage.

Furthermore, during state monitoring, the constraints of the system are not considered, for example the application, interfering influences from the environment, the installation, etc. These may influence the robustness and reliability of the state monitoring.

Motor applications (pumps, fans) are monitored by manually configuring limits that are based on standards. Drawing a distinction according to operating points does not exist at present. In this case, the constraints are not considered either.

CN 111 985 546 A discloses a method.

Documents CN 111 275 198 A, WO 2021/175493 A1, US 2020/285997 A1, US 2021/133559 A1, US 2016/342903 A1 and DE 10 2019/110721 A1 disclose various aspects of a method.

### BRIEF SUMMARY AND DESCRIPTION

The scope of the embodiments is defined solely by the appended claims and is not affected to any degree by the statements within this summary. The present embodiments may obviate one or more of the drawbacks or limitations in the related art.

Embodiments improve the monitoring of such machines, for example of motors, and thus of preventing machine damage as a result of unfavorable operating conditions.

Embodiments provide a method for monitoring the operation of a machine, in particular of a motor or electrically driven motor including a training phase and an application phase. The training phase includes providing training data comprising state variables of multiple operating points of the machine, recognizing and combining operating points of the training data by way of clustering to form operating-point clusters, training a classifier that assigns operating points to the recognized operating-point clusters, and training at least one anomaly recognition model to carry out operating anomaly recognition. The application phase includes recording operating data comprising state variables of operating points of the machine in an operating state, assigning the operating data to the operating-point clusters by way of the classifier, and recognizing operating anomalies by way of the at least one anomaly recognition model.

In order to improve monitoring, embodiments provide a method wherein the at least one anomaly recognition model calculates an anomaly characteristic value (or anomaly score) the value of which describes the severity of the anomaly. An anomaly or an anomaly type is recognized when the anomaly characteristic value exceeds a predetermined threshold value.

A state variable is a macroscopic physical variable. State variables may be used to describe the state of a physical system. By way of example, this may involve thermodynamic pressure, temperature or else variables from other scientific disciplines, such as for example speed, force, torque, voltage, current, power output, efficiency or volume.

In an embodiment, the at least one anomaly recognition model is an unsupervised model.

An unsupervised model is understood to mean a model—that is to say a simplified portrayal of reality—that is configured to carry out machine learning without specific target values of the learning process being defined beforehand. In this case, the unsupervised model, in the input data, recognizes patterns that deviate from unstructured noise. One option for implementing the unsupervised model includes the use of artificial neural network algorithms. These are oriented toward the similarity of input values and adapt themselves accordingly. In this case, it is possible to automatically create a clustering (segmentation or grouping).

In an embodiments, operating points include measured values of at least one of the following types: vibration, temperature, torque, supplied power, output power, efficiency (for example electrical or thermal efficiency), energy consumption, electric current, voltage, frequency, supply voltage (in the case of inverter-fed electric motors).

In an embodiment, the training data includes multiple operating points and/or historical data and/or reference measurements and/or fingerprints. The training data may originate from the same machine or a group of identical machines. It is also possible to use simulated data or data from similar machines. In this case, the method may include further steps, for example: preprocessing the training data and/or operating data by way of data cleansing and/or data scaling, for example using further data sources and/or data from a digital twin and/or machine nominal values.

In an embodiment, the anomaly or the anomaly type is recognized as a faulty operating point, for example the anomaly recognition model isolates the operating point at which the anomaly is visible or occurs. It may also be expedient to assign a respective one of different types of anomaly to an operating state based on the anomaly characteristic value and multiple threshold values, wherein each type of anomaly may have its own threshold value. By way of example, a low anomaly characteristic value may indicate a normal state, a medium one may indicate the need for a specific upcoming maintenance requirement and a high one may indicate the need to shut down the machine.

In an embodiment the method includes the further steps of: displaying the anomaly characteristic value and/or recommendations based on the anomaly characteristic value with regard to operating the machine and/or controlling, for example automatically controlling the machine, such that the current operating point of the machine changes.

An arrangement may be linked to one or more possibly different human/machine interfaces. In this case, it is expedient for provision to be made, among these human/machine interfaces, for at least one display, such that anomaly characteristic values and/or recommendations based on anomaly characteristic values with regard to operating the machine are able to be displayed.

In an embodiment, the classifier is a supervised model, for example operating in accordance with the nearest centroid or random forest method, or as a neural network.

In an embodiment a respective separate anomaly recognition model may be assigned to the individual operating-point clusters, for example where a respective separate anomaly recognition model is assigned to each operating-point cluster. This architecture enables particularly efficient recognition of the anomalies, because the anomalies may generally occur in an operating-point cluster-specific manner. The classification into operating-point clusters and the modeling of the anomaly recognition specifically for these clusters, makes the individual anomaly recognition models faster and more efficient than in the case of anomaly recognition without previous cluster formation. The separate assignment of an anomaly recognition model to a respective operating-point cluster concerns both the training phase and the application phase. In other words, the individual anomaly recognition models are trained in an operating-point cluster-specific manner in the training phase, and then applied in the anomaly recognition model in an operating-point cluster-specific manner in the application phase in order to recognize anomalies.

Embodiments further provide a computer program product for performing a method as described herein, described embodiments, or according to at least one or a combination by way of at least one computer. The computer program product may be stored on a data carrier and be able to be transported, divested or used in some other way by way of this data carrier and/or by way of downloads from the data carrier.

Embodiments further provide an arrangement, for example including at least one computer for performing a method according to at least one or a combination of the embodiments by way of at least one computer. The arrangement includes the at least one computer prepared to perform the method. The computer may be prepared with a computer program product to carry out the method. The computer may also be a computer network, wherein the method may be applied by way of multiple computers that execute the method in parallel or together. As an alternative or in addition, the computer may be configured as an edge device, for example arranged in the spatial environment or in the for example direct vicinity of the machine or installed on the machine. The arrangement may for example also include the machine, for example a motor, for example an electric motor, for example including an inverter.

In an embodiment, a machine, for example a motor and the application data thereof, is monitored in an operating point-specific manner. The various operating points are automatically detected and grouped by way of clustering algorithms. An unsupervised model is then trained to carry out anomaly recognition for each operating point. Different variables (for example vibration, temperature, etc.) may thus be monitored within each detected operating point.

A supervised classifier is furthermore created based on the clustering results in order to classify the operating points during operation. Historical data in the form of fingerprints/reference measurements form the basis for the creation.

A fingerprint is intended to be created at the beginning of the training phase of the possible implementation. The fingerprint is a set of measurements from sensors (for example Siemens SIMOTICS CONNECT 400) or other data sources (for example motor digital twin) within a defined time range and describes the reference behavior or normal behavior of the motor application. The fingerprint contains multiple operating points. This provided fingerprint is preprocessed, fore example including where data cleansing and data scaling are performed, in order to obtain a usable standard. Other data sources may also be used for the preprocessing, for example motor nominal values that have been obtained from a digital twin of the motor.

In an embodiment, the preprocessed data are then used as input for the clustering algorithm that is based on machine learning (for example hierarchical clustering). The operating points are clustered on the basis of speed curves and torque curves in the fingerprint, but other values may also be used. The identified clusters are then used to train a tested classifier (for example nearest centroid or random forest classifier or one designed as a neural network) to classify new data in a cluster.

For each cluster, an anomaly recognition model based on one or more KPIs (for example vibration, temperature, etc.) is implemented.

The models are then stored in order to be applied later to new data.

An application phase provides for the created models to be applied to new measurements in order to recognize anomalies. A new measurement is assigned to a specific operating point. The corresponding anomaly recognition model is then triggered and calculates an anomaly characteristic value or anomaly score that describes the severity of the anomaly. Based on the anomaly characteristic value, specific recommendations/activities may be triggered.

The models recognize, even during operation, when a new measurement does not belong to a known operating point, for example where the application is running at a new operating point. In this case, the method may provide for the model in question or the models either to be automatically retrained or for a recommendation to be given via a human/machine interface to perform a training phase.

Embodiments provide early recognition of faults and anomalies in order to avoid unplanned stoppages and better planning of maintenance activities, efficiency in terms of maintenance and troubleshooting as a result of isolating the anomaly according to operating point, extending production by changing to a safe operating point and avoiding critical operating points, and distinction between operation-related anomalies (for example blockages in the pump) and anomalies caused by increased vibrations (imbalance, misalignment, bearing damage, etc.).

### BRIEF DESCRIPTION OF THE FIGURE

FIG. 1 depicts a schematic flowchart of a method according to an embodiment.

### DETAILED DESCRIPTION

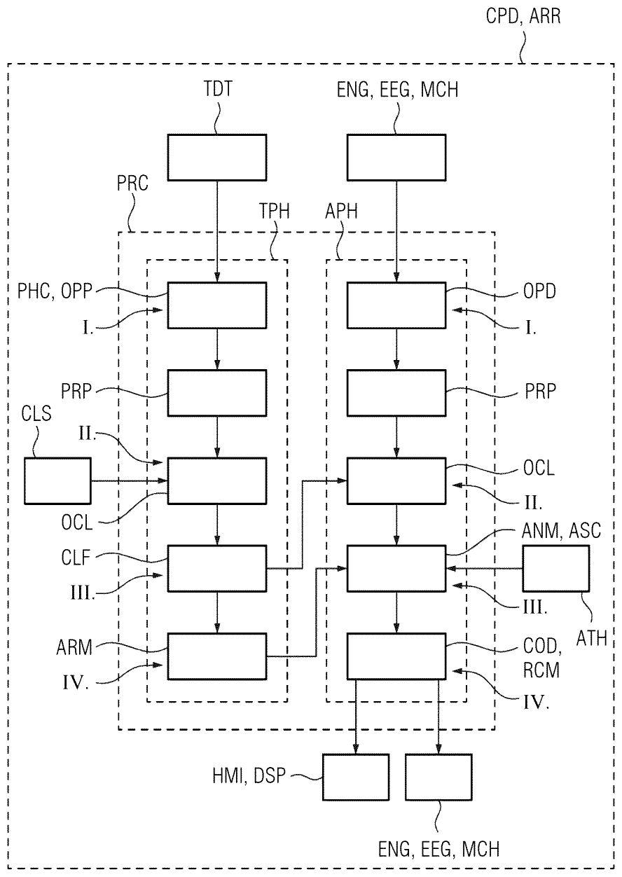

FIG. 1 depicts a schematic flowchart of a method PRC for monitoring the operation of a machine MCH, here a motor ENG that is configured as an electrically driven motor EEG. A computer program product CPD concerns the method PRC and is indicated schematically in FIG. 1, wherein the computer program product CPD is stored on a data memory and, when executed on at least one computer, prompts the computer to carry out the method. The method is accordingly computer-implemented. The computer and possibly the machine (for example including a motor) in this case corresponds to an arrangement ARR.

A training phase TPH is performed in multiple steps.

In a step I., training data TDT including state variables PHC of multiple operating points OPP of the machine MCH are provided. The training data TDT include multiple operating points OPP and/or historical data and/or reference measurements and/or fingerprints.

In a step II., operating points OPP of the training data TDT are recognized by way of clustering CLS and combined to form operating-point clusters OCL.

In a step III., a classifier CLF is trained to assign the operating points OPP to the recognized operating-point clusters OCL. The classifier CLF operates in accordance with the nearest centroid or random forest method.

In a step IV., anomaly recognition models ARM are trained to perform operating anomaly recognition.

Embodiment may provide a respective separate anomaly recognition model ARM to be assigned to the individual operating-point clusters OCL, for example wherein a respective separate anomaly recognition model ARM is assigned to each operating-point cluster OCL.

The training phase TPH is followed by an application phase APH. The application phase APH begins, in a step I., with the recording of operating data OPD including state variables PHC of operating points OPP of the machine MCH in a specific operating state. In a step II., the operating data OPD are assigned to the operating-point clusters OCL by way of the classifier CLF from the training phase TPH. The operating data OPD or operating points OPP include measured values of at least one of the following types: vibration, temperature, torque, pressure, current, voltage, power output. In a step III., the at least one trained, operating-point cluster-specific anomaly recognition model ARM recognizes operating anomalies ANM. The anomaly recognition model ARM is in this case an unsupervised model.

In a step PRP between steps I. and II., both of the training phase TPH and of the application phase APH (for example just one of the two phases), the training data TDT and/or operating data OPD are preprocessed by way of data cleansing and/or data scaling, for example using further data sources and/or data from a digital twin and/or machine nominal values.

To classify a recognized operating anomaly ANM, the anomaly recognition model ARM calculates an anomaly characteristic value ASC. This value describes the severity of the anomaly. An operating anomaly ANM is recognized when the anomaly characteristic value ASC exceeds a predetermined threshold value ATH.

In a step IV., depending on the operating anomaly ANM: the anomaly characteristic value ASC and/or at least one recommendation RCM based on the anomaly characteristic value ASC with regard to operating the machine MCH are/is displayed, and/or the machine MCH is automatically controlled by way of a control command COD, such that the current operating point OPP of the machine MCH changes.

It is to be understood that the elements and features recited in the appended claims may be combined in different ways to produce new claims that likewise fall within the scope of the present embodiments. Thus, whereas the dependent claims appended below depend from only a single independent or dependent claim, it is to be understood that these dependent claims may, alternatively, be made to depend in the alternative from any preceding or following claim, whether independent or dependent, and that such new combinations are to be understood as forming a part of the present specification.

While the present embodiments have been described above by reference to various embodiments, it may be understood that many changes and modifications may be made to the described embodiments. It is therefore intended that the foregoing description be regarded as illustrative rather than limiting, and that it be understood that all equivalents and/or combinations of embodiments are intended to be included in this description.

1. A method for monitoring an operation of a machine of a motor or an electrically driven motor, the method comprising a training phase and an application phase, wherein the training phase comprises:
providing training data comprising state variables of operating-points of the machine;
recognizing and combining operating-points of the training data by way of clustering to form operating-point clusters;
training a classifier that assigns operating-points to the recognized operating-point clusters; and
training at least one anomaly recognition model to carry out operating anomaly recognition;
wherein the application phase comprises:
recording operating data comprising state variables of operating-points of the machine in an operating state;
assigning the operating data to the operating-point clusters by way of the trained classifier; and
recognizing operating anomalies by way of the at least one anomaly recognition model, wherein the anomaly recognition model calculates an anomaly characteristic value the value of which describes a severity of the anomaly, wherein an anomaly and/or an anomaly type is recognized when the anomaly characteristic value exceeds a predetermined threshold value.

2. The method of claim 1, wherein the anomaly recognition model is an unsupervised model.

3. The method of claim 1, wherein the operating-points and the operating data comprise measured values of at least one of the following types: vibration, temperature, torque, pressure, current, voltage, or power output.

4. The method of claim 1, wherein the training data comprises multiple operating-points and/or historical data and/or reference measurements.

5. The method of claim 1, further comprising:
preprocessing the training data and/or the operating data using data cleansing and/or data scaling, using further data sources and/or data from a digital twin and/or machine nominal values.

6. The method of claim 1, further comprising:
displaying the anomaly characteristic value and/or recommendations based on the anomaly characteristic value with regard to operating the machine and/or
controlling, in particular automatically controlling the machine, such that the current operating-point of the machine changes.

7. The method of claim 1, wherein the classifier is configured as a neural network or operates in accordance with a nearest centroid method or a random forest method.

8. The method of claim 1, wherein a respective separate anomaly recognition model is assigned to individual operating-point clusters, wherein a respective separate anomaly recognition model is assigned to each operating-point cluster.

9. (canceled)

10. (canceled)

11. A non-transitory computer implemented storage medium that stores machine-readable instructions executable by at least one processor for monitoring an operation of a machine of a motor or an electrically driven motor, the machine-readable instructions comprising:
a training phase comprising:
providing training data comprising state variables of operating-points of the machine;
recognizing and combining operating-points of the training data by way of clustering to form operating-point clusters;
training a classifier that assigns operating-points to the recognized operating-point clusters;
training at least one anomaly recognition model to carry out operating anomaly recognition; and
an application phase comprising:
recording operating data comprising state variables of operating-points of the machine in an operating state;
assigning the operating data to the operating-point clusters by way of the trained classifier; and
recognizing operating anomalies by way of the at least one anomaly recognition model, wherein the anomaly recognition model calculates an anomaly characteristic value the value of which describes a severity of the anomaly, wherein an anomaly and/or an anomaly type is recognized when the anomaly characteristic value exceeds a predetermined threshold value.
